(19) United States
(12) Patent Application Publication
(10) Pub. No.: US 2006/0198183 A1
(43) Pub. Date: Sep. 7, 2006

(54) Semiconductor device

(76) Inventors: Takayuki Kawahara, Higashiyamato (JP); Kenichi Osada, Tokyo (JP); Riichiro Takemura, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/337,648

(22) Filed: Jan. 24, 2006

(30) Foreign Application Priority Data
Mar. 1, 2005 (JP) 2005-056010

(51) Int. Cl. G11C 11/00

(52) U.S. Cl. 365/163

(57) ABSTRACT

With a semiconductor device using a phase change material, in particular, an increase in the number of circuit elements associated with a testing function is checked to the minimum, and an easier test on the semiconductor device is implemented. When a retention test and so forth are conducted on a phase change element, for example, a generated voltage VS1 of a set bit-line voltage power supply, VG_set, provided originally for use in a set operation, is used as a voltage to be applied to the phase change element, and timing when the voltage VS1 is applied to the phase change element is generated by a read/test timing generation circuit TG_rd_test, provided originally to execute a read operation of the phase change element. By so doing, it becomes possible to check an increase in the number of circuit elements, and to conduct the retention test accelerated on a voltage basis with ease.

### CLAIM OF PRIORITY

The present application claims priority from Japanese application JP 2005-056010 filed on Mar. 1, 2005, the content of which is hereby incorporated by reference into this application.

### FIELD OF THE INVENTION

The invention relates to a semiconductor device, and in particular, to a technology effective for application to a semiconductor device incorporating a phase change memory, and a test circuit thereof.

### BACKGROUND OF THE INVENTION

According to the results of studies conducted by the inventors, the following is conceivable in connection with a technology concerning a memory using a phase change material.

An advance has since been made in development of a technology referred to as “a phase change memory”. This is a technology whereby a phase change film, and a phase change element, in use for an optical disk, such as a field programmable CD, DVD, and so forth, are used in a memory cell, and “0” and “1” are stored depending on whether the phase change element is in an amorphous state or in a crystallization state. With the optical disk, localized heating is applied thereto using a high-output laser, and writing is effected by creating the amorphous state, and the crystallization state.

Meanwhile, with the phase change memory, writing is effected by applying localized heating thereto using a current pulse, and reading is effected by detecting variation in electrical resistance value, due to a change in phase state. In order to implement this, the output of a transistor is provided with a heater part, to which a phase change element is connected, and a metal is connected to the other part of the transistor to thereby allow current to flow therethrough as described in “Ovonic Unified Memory-A High-performance Nonvolatile Memory Technology for Stand Alone Memory and Embedded Applications” by M. Gill, T. Lowery, J. Park, Proceedings of 2002 IEEE International Solid State Circuits Conference, February, 2002. In this way, it is possible to cause current to flow through only a portion selected by the transistor.

A rewrite operation includes an operation called resetting whereby the phase change element is melted once by causing a large current to flow thereto and subsequently, the phase change element is caused to undergo rapid cooling by stopping supply of the current (the phase change element is turned into the amorphous state where electrical resistance is high) and a set operation whereby a current smaller than the current described as above is caused to flow continuously for a given period of time, and the phase change element is caused to undergo crystallization due to heat generated during the period (in the crystallization state, electrical resistance is low). In reading, the transistor is turned ON, and magnitude of resistance of the phase change element at this point in time is read on the basis of a current flowing through the transistor.

### SUMMARY OF THE INVENTION

Now, the inventors have reviewed a technology for testing a memory using the phase change material as described above, and as a result, the following has become evident.

With the phase change memory described, it is essential to develop a testing method for screening initial faults. Particularly, in the case of a nonvolatile memory such as the phase change memory, whether or not data as held can be kept for a period of, for example, ten years is an important item, which need be tested at a high speed.

The inventors have found out during the review that in the case of the phase change memory, a mechanism of deterioration at the time of reading, and so forth is equivalent to a mechanism of deterioration at the time when the phase change memory is left unattended. Herein, the mechanism of deterioration is described by comparing the phase change memory with, for example, a flash memory as a representative nonvolatile memory.

FIG. 15 is a graph showing an example of the characteristic of a phase change memory element on which the present invention is based. In the figure, the horizontal axis indicates the reciprocal of the product of an absolute temperature T and Boltzmann constant k, and the vertical axis indicates a retention time. The retention time refers to a time length for which stored information of the element is kept at a temperature. With a nonvolatile memory such as the phase change memory, the retention time is an important item for evaluation. When the characteristic of a normal phase change memory element is plotted in the graph, the characteristic thereof is represented by a line S2 that falls between lines S1, S3. Herein, only one line is shown as S2; however, S2 represents an optional line between the lines S1, S3, and the line S1 and the line S3 indicate the upper limit and the lower limit of variation, respectively. If the characteristic falls in a region between the lines S1, S3, a desired retention time t2 can be achieved at the temperature T2.

However, the characteristic of an abnormal phase change memory element falls outside a region described as above. In such a case, the characteristic becomes ones as indicated by lines S4, and S5, respectively. With such a phase change memory element as described, the desired retention time t2 can no longer be achieved at the temperature T2. Hereupon, the unique property of the phase change element is put to use.

More specifically, in the case of the phase change element, heat is generated even when executing, for example, normal reading, and so forth, thereby causing the temperature of a memory cell element to rise. This phenomenon is equivalent to a state of retention characteristic when the temperature is raised in FIG. 15. If so, the retention time becomes shorter by raising the temperature along one and the same line in FIG. 15. That is, reading is equivalent to giving a disturbance, which is equivalent to an event as seen when the retention characteristic is accelerated.

The fact that the disturbance, and retention are based on the same characteristic represents a significant characteristic of the phase change element. The higher a voltage, the greater an acceleration becomes. Or, by taking longer time (lengthening disturbance time), the retention characteristic can be reproduced. With the nonvolatile memory such as the phase change memory, the retention time is an important item for evaluation, and it is the main object of screening at a test to determine whether or not the retention time is acceptable.

With the present invention, advantage is taken of “the fact that the disturbance characteristic, and the retention characteristic are based on the same mechanism in the case of the phase change element,” as found out by the inventors, et al. More specifically, a slightly large current is caused to flow to a memory element at the test to thereby raise temperature, and an extent of deterioration occurring to the memory element is checked. Suppose, for example, the temperature T1 was given. Then, if the characteristic is found falling in regions among the normal lines S1, S2, and S3, respectively, the element holds normal memory information even with the elapse of time t1. However, in the case of a phase change element indicated by the lines S4, S5, respectively, representing abnormal properties, the phase change element cannot hold the normal memory information with the elapse of the time t1. Thus, it is possible to remove abnormal elements, or to find out a condition insusceptible to occurrence of abnormality on the basis of such test results.

Meanwhile, a mechanism of deterioration in a flash memory is described as follows. FIG. 16 is a view for describing the mechanism of deterioration in the flash memory, in which FIG. 16Ais a schematic diagram showing an information-holding state (retention), and FIG. 16B is a schematic diagram showing a read state. With the flash memory, such two different physical mechanisms as described are dominant. More specifically, as shown in FIG. 16A, in the retention, electrons inside a floating gate are excited by heat, and tunnel through an insulating film to come out thereof, thereby causing deterioration to occur. Such a characteristic as described is more prone to occur according as the temperature rises and is the same in nature as that shown in, for example, FIG. 15.

On the other hand, in the disturbance, a portion of current flowing from a drain to a source at the time of reading as shown in FIG. 16B has high energy, and jumps into the floating gate, whereupon written information undergoes a change, thereby causing deterioration to occur. This phenomenon is largely dependent on a voltage, but its dependence on temperature is not so large as that in the case of tunneling on which the retention depends.

Now, reverting to the test, presence of the two physical mechanisms means the necessity for conducting two different tests. For this reason, with the flash memory, a test on the retention and a test on the disturbance are generally conducted independently from each other at different temperatures, respectively. This results in an increase in test time for the flash memory.

In contrast, with the phase change memory, if the same operation as normal reading is executed by slightly raising a voltage, or slightly lengthening the test time, testing on both the retention characteristic and the disturbance characteristic can be simultaneously conducted. It is therefore an object of the invention to provide a semiconductor device capable of checking an increase in the number of circuit elements associated with a testing function to the minimum by taking advantage of those characteristics, and implementing easier testing. Further, it is another object of the invention to provide a semiconductor device capable of implementing shorter test time.

The above and further objects and novel features of the invention will appear more fully hereinafter from the following detailed description taken in connection with the accompanying drawings.

The outlines of the representative ones of the embodiments of the invention, disclosed under the present application, are briefly described as follows.

A semiconductor device according to the invention is provided with circuits capable of executing a test operation by utilizing a voltage applied to a memory element or timing applied thereto when turning the memory element into the crystallization state (at the time of a set operation), in combination with a voltage applied to the memory element or timing applied thereto when executing a read operation of the memory element. In this context, the test operation means the so-called retention test, however, it is possible to concurrently execute a disturbance test. That is, by executing the retention test, the disturbance test is also executed at the same time, thereby shortening test time.

As for a specific voltage and timing at the time of the test operation, there is cited, for example, a system for applying a voltage at the time of the set operation to the memory element at timing for a read operation. In this case, as a voltage generation circuit and a timing generation circuit can be shared with the circuits originally provided, reduction in area can be achieved. As a result, it becomes possible to easily conduct the retention test accelerated on a voltage basis within a scope where the set operation cannot be executed to a normal memory element.

Further, in contrast with the system described, it is also possible to generate either a voltage or timing through shared use of circuits as originally provided while generating the other by use of a circuit separately provided. In the case of generating a voltage by use of the circuit separately provided, the voltage is preferably higher than the voltage at the time of the read operation, and is lower than the voltage at the time of the set operation. Further, in the case of generating timing by use of a circuit separately provided, the timing need be shorter than timing at the time of the set operation. In those cases as well, shared use of portions of the circuits originally provided is possible when generating the voltage or the timing, so that reduction in area can be implemented. Then, it becomes possible to easily conduct the retention test accelerated on a voltage basis or a voltage application time basis within the scope where the set operation cannot be executed to the normal memory element.

Still further, as for another example of the specific voltage and timing at the time of the test operation, there is cited a method for applying a voltage at the time of the read operation to the memory element at timing for the set operation. In this case, it is possible to achieve reduction in area as previously described, and the retention test accelerated on the voltage application time basis can be easily conducted.

Furthermore, those systems are particularly useful for application to a semiconductor device comprising a memory element composed of a chalcogenide material.

To briefly describe advantageous effects of the representative embodiments of the invention, disclosed under the present application, it becomes possible to implement an easier test on a semiconductor device comprising a phase change memory, in particular. Also, it becomes possible to shorten test time.

### BRIEF DESCRIPTION OF THE DRAWINGS

FIG. 1 is a block diagram showing an example of a configuration of a semiconductor device according to one embodiment of the invention;

FIG. 2 is a block diagram showing an example of another configuration of the semiconductor device according to the embodiment, differing from the configuration shown in FIG. 1;

FIG. 3 is a table showing a method whereby generation of a bit line voltage, and timing generation are shared among a normal read operation, set operation, and reset operation in a test operation using the configurations shown in FIGS. 2, and 3, respectively.

FIG. 4 is a table as a variation of the table in FIG. 3, showing a method for sharing the generation of the bit line voltage, and the timing generation;

FIG. 5 is a waveform chart showing an example of operations corresponding to the table in FIG. 3, in which FIGS. 5A, 5B, 5C, and 5D show the reset operation, set operation, read operation, and test operation, respectively;

FIG. 6 is a waveform chart showing an example of operations corresponding to the table in FIG. 4, in which FIGS. 6A, 6B, 6C, and 6D show the reset operation, set operation, read operation, and test operation, respectively;

FIG. 7 is a block diagram showing an example of still another configuration of the semiconductor device according to the embodiment, differing from the configuration shown in FIG. 1;

FIG. 8 is a block diagram showing an example of a further configuration of the semiconductor device according to the embodiment, differing from the configuration shown in FIG. 1;

FIG. 9 is a waveform chart showing an example of operations when the configuration in FIG. 8 is adopted, in which FIGS. 9A, 9B, 9C, and 9D show the reset operation, set operation, read operation, and test operation, respectively;

FIG. 10 is a circuit diagram of the semiconductor device according to the embodiment of the invention, showing an example of a detailed configuration thereof, including a memory array configuration;

FIG. 11 is a waveform chart showing an example of an operation in the case of adopting the configuration shown in FIG. 10;

FIG. 12 is a circuit diagram showing examples of the configuration of the memory cells in FIG. 10, and so forth, in which FIGS. 12A, and 12B each are the examples of the memory cell comprising a MOS transistor, and a phase change element, and FIGS. 12(c-1), 12(c-2), 12(d-1), and 12(d-2) each are the examples of the memory cell comprising a bipolar transistor, and a phase change element;

FIG. 13 is a sectional view showing an example of a configuration of the semiconductor device according to the embodiment of invention;

FIG. 14 is a sectional view showing an example of another configuration of the semiconductor device according to the embodiment of invention, differing from that shown in FIG. 13;

FIG. 15 is a graph showing an example of the characteristic of a phase change memory element on which the present invention is based; and

FIG. 16 is a view for describing the mechanism of deterioration in a flash memory, in which FIG. 16A is a schematic diagram showing an information-holding state (retention), and FIG. 16B is a schematic diagram showing a read state.

### DETAILED DESCRIPTION OF THE PREFERRED EMBODIMENTS

Embodiments of the invention are described in detail hereinafter with reference to the accompanying drawings. In all the figures for describing the embodiments of the invention, identical members are, in principle, denoted by like reference numerals, thereby omitting repeated description thereof. Further, circuit elements constituting respective function blocks of the embodiments are formed over a semiconductor substrate such as one made of single crystal silicon by use of an IC technology such as the public known CMOS (Complementary MOS transistor), and so forth although not particularly limited thereto.

In the figures, the gate of a pMOS transistor is marked by a symbol of a circle to be thereby distinguished from an nMOS transistor. Further, in the figures, connection of the substrate potential of a MOS transistor is not particularly stated, but a method of connection thereof is not particularly limited as long as the MOS transistor is in a normal operation range.

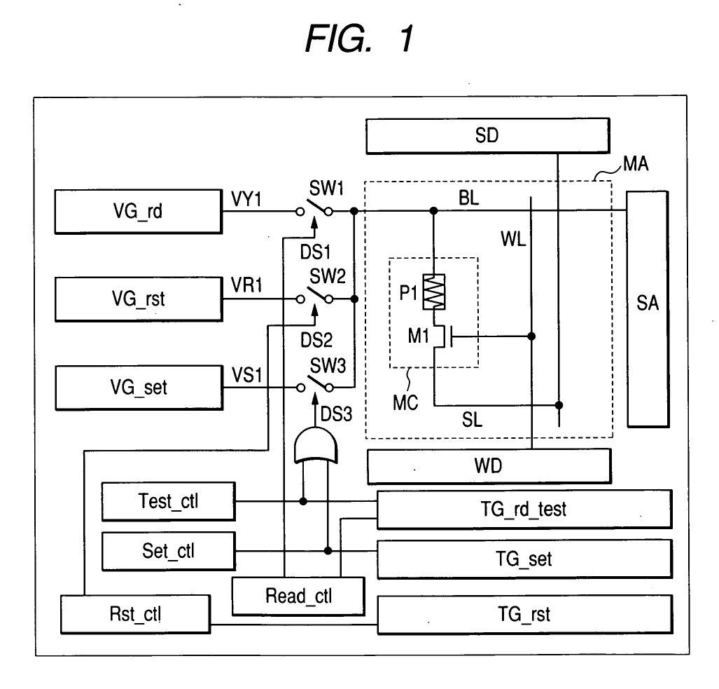

FIG. 1 is a block diagram showing an example of a configuration of a semiconductor device according to one embodiment of the invention. In FIG. 1, the semiconductor device is characterized in that a set bit-line voltage power supply, VG_set, is used for both a set operation and a test operation, a method and a function for achieving such a purpose are provided, and large portions of respective timing generation circuits for a read operation and the test operation make the common use of a timing generation circuit for read/test time, TG_rd_test. The inventors have found out that it is possible by doing so to execute an effective test operation adaptable to the characteristic of material of a phase change memory, as previously described, and by focusing attention on this, it becomes possible to check an increase in the number of circuits as small as possible.

To describe the configuration in more details hereinafter, memory cells MC (only one thereof is shown in the figure) are two-dimensionally spread all over a memory array MA, and the respective memory cells MC comprise a transistor M1, and a phase change element P1, the respective memory cells MC being rendered selectable according to a relationship in voltage among a bit line BL, word line WL, and source line SL. A source driver SD is a circuit for driving the source line SL, a word driver Wd is a circuit for driving the word line WL, and a sense amplifier SA is a circuit for amplifying a signal voltage emerging in the bit line BL.

The phase change memory executes the set operation, a reset operation, the read operation, and the test operation, and in order to execute the respective operations, there are requirements for a set control circuit Set_ctl, reset control circuit Rst_ctl, read control circuit Read_ctl, and test control circuit Test_ctl, respectively, thereby causing time intervals necessary for the respective operations, and timing of operation-start signals, and so forth to be generated at a set timing generation circuit TG_set, reset timing generation circuit TG_rst, and the read/test timing generation circuit TG rd_test, respectively. As described above, the present invention is characterized in that at this point in time, the large portions of the respective timing generation circuits for the read operation and the test operation make the common use of the timing generation circuit for read/test time, TG_rd_test and large portions of those circuits also are for common use. Further, transition from a normal operation to the test operation is effected by an input of a command from outside, or an input from a test terminal.

Further, with the phase change memory, a plurality of voltages are used, however, with the present embodiment, there is shown an example wherein upon the execution of the set operation, reset operation, read operation, and test operation, respectively, a voltage applied to the phase change element P1 is changed by switching over the voltage of the bit line BL. That is, the phase change memory according to the present embodiment has a set bit-line voltage power supply VG_set (VS1 generated), reset bit-line voltage power supply VG_rst (VR1 generated), and read bit-line voltage power supply VG_rd (VY1 generated). A relationship in magnitude among those generated voltages is generally expressed as follows:
VR1>VS1>VY1

The reason for the above is that rewrite of the phase change element depends on the magnitude of heat as given and at the time of the reset operation, heat large in magnitude is given (to be then rapidly taken away) at VR1 while at the time of the set operation, heat smaller in magnitude than the former is given. On the other hand, for reading, heat given is preferably as small as possible in magnitude, so that a voltage becomes lower. The reason why the heat given at the time of reading is preferably small in magnitude is to minimize the so-called disturbance as given, where the state of phase change undergoes a change due to the heat. Further, if the phase change element is left unattended in an environment, this will cause the phase change element to reach a stable state. Time elapsed between a rewrite state and the stable state is called a retention time (in practice, time required for electrical change from the initial resistance state to a specified resistance value).

In this connection, the present embodiment has a feature in that a separate power supply for use in testing is not prepared, and in the case of conducting a disturbance test and a retention test, use is made of the set bit-line voltage power supply VG_set instead of the read bit-line voltage power supply VG_rd as normally used. By so doing, it becomes possible to conduct an accelerated test with the use of a voltage setting on a higher side than for a voltage at a normal read operation. Then, a power supply voltage, and timing, necessary for the test operation on phase change can be created from respective power supply voltages and timing necessary for the set operation, reset operation, and read operation.

As described above, by conducting the test operation with the use of the timing for the read operation, and the voltage for the set operation, it becomes possible to check an increase in the number of elements and an increase in chip area to thereby conduct the test operation with ease. Furthermore, since the disturbance test and retention test can be concurrently conducted, shorter test time can be achieved.

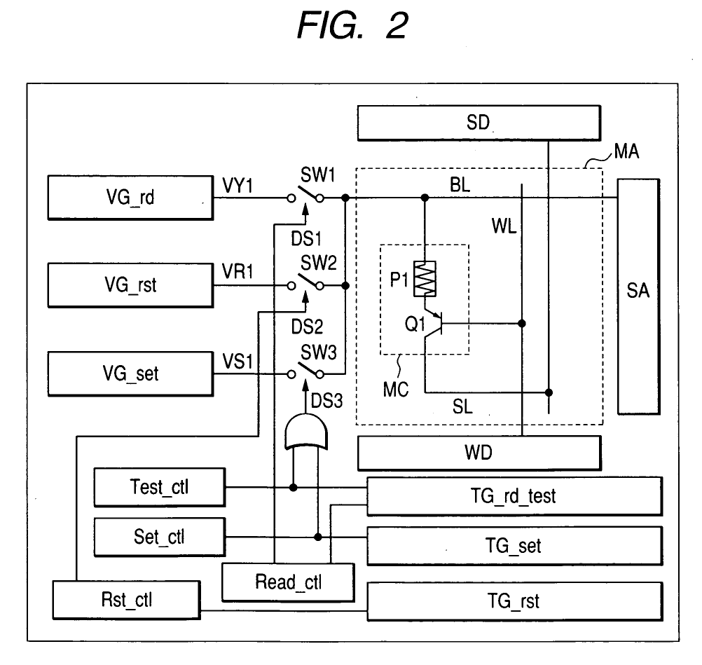

FIG. 2 is a block diagram showing an example of another configuration of the semiconductor device according to the embodiment, differing from the configuration shown in FIG. 1. In FIG. 2, the semiconductor device is characterized in that use is made of memory cells MC each using a bipolar transistor Q1. As a result, in the case of a process for fabricating the bipolar transistor Q1, or a cell structure using the bipolar transistor Q1, it is generally expected that a large current is caused to flow as compared with the case of using a Mos transistor, and a test operation at that time can be conducted with ease while checking an increase in the number of elements and an increase in chip area.

In this case, there is described the case of a pnp bipolar transistor. A phase change element P1 is inserted between the emitter terminal of the bipolar transistor Q1, and a bit line BL. The configuration of the semiconductor device, in other respects, is the same as that shown in FIG. 1, and is characterized in that a power supply voltage and timing, necessary for the test operation on phase change can be created from respective power supply voltages and timing necessary for the set operation, reset operation, and read operation.

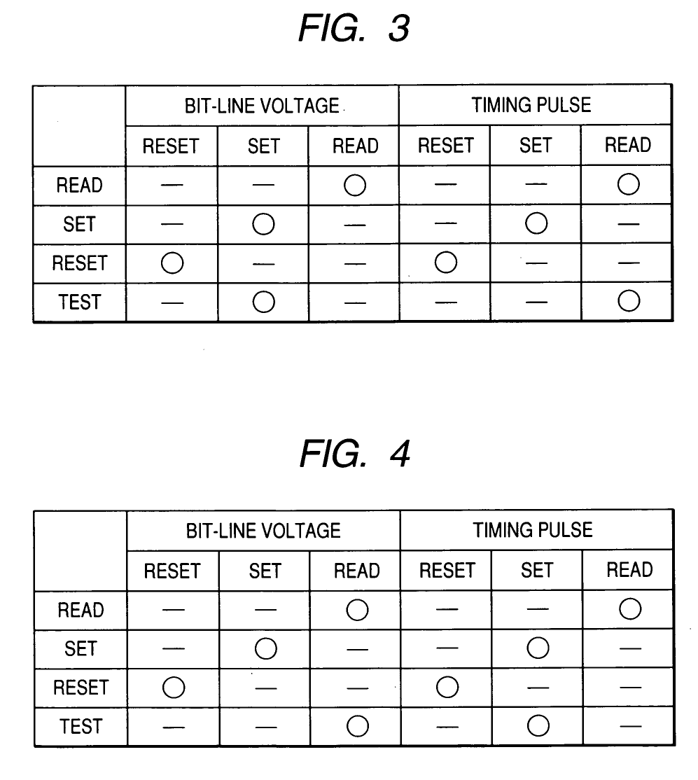

FIG. 3 is a table showing a method whereby generation of the bit line voltage and timing generation are shared among the normal read operation, set operation, and reset operation in the test operation using the configurations shown in FIGS. 2, and 3, respectively. In the read operation, use is made of a read bit-line voltage, and a read timing pulse. In the set operation, use is made of a set bit-line voltage and a set timing pulse. Further, in the reset operation, use is made of a reset bit-line voltage and a reset timing pulse.

Meanwhile, in the test operation according to the present embodiment, portions of the respective the bit-line voltages, and timing pulses of those normal operations are utilized. More specifically, in the test operation, use is made of the set bit-line voltage and the read timing pulse. By so doing, the test operation can be conducted with ease while checking an increase in the number of the elements and an increase in the chip area. Further, it becomes possible to shorten the test time

FIG. 4 is a table as a variation of the table in FIG. 3, showing a method for sharing the generation of the bit line voltage and the timing generation. More specifically, in this case, use is made of the read bit-line voltage and the set timing pulse. Consequently, even in the test operation as well, the read bit-line voltage is used at the power supply. A method for making such a selection is needed, but the method can be easily inferred from the method shown in FIG. 3, and it need only be sufficient to control a switch SW1 for connecting the read bit-line voltage power supply VG_rd to the bit line BL through the read control circuit Read_ctl, and the test control circuit Test_ctl, thereby enabling the power supply to be shared by both the read operation and test operation. Further, timing generation during the test operation may be effected not by the read timing pulse as shown in FIG. 3, but through shared use of a substantial portion of the set timing generation circuit TG_set.

Even then, it is possible to conduct the accelerated test by applying a voltage for a time length longer than that for a normal case without altering the essence of the invention. In addition, the test operation can be conducted with ease while checking an increase in the number of elements for testing, and an increase in chip area. Further, it becomes possible to shorten the test time.

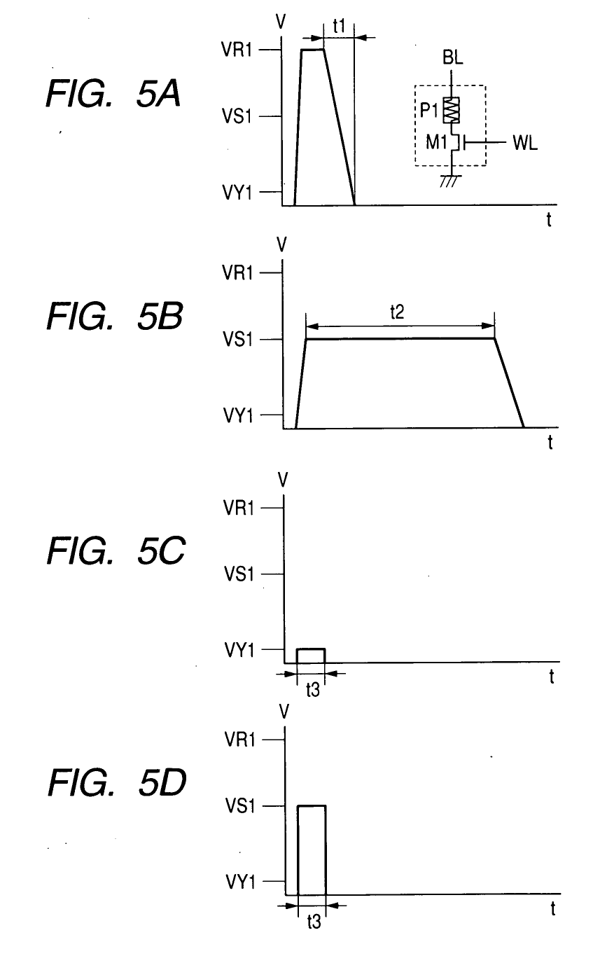

FIG. 5 is a waveform chart showing an example of the operations corresponding to the table in FIG. 3, in which FIGS. 5A, 5B, 5C, and 5D show the reset operation, set operation, read operation, and test operation, respectively. In FIG. 5, the horizontal axis is a time axis t, and the vertical axis indicates bit line voltages V applied at respective times along the time axis t. Symbols t1, t2, and t3 indicate characteristic time lengths, respectively, and t1 designates a time length when a voltage is lowered from VR1 to 0V in the reset operation, t2 a time length when the voltage is held at the given voltage VS1 in the set operation, and t3 a time length when the voltage is held at the read bit-line voltage VY1 in the read operation. Those voltages indicate voltages applied to the bit lines BL, respectively, for the respective memory cells MC selected by the respective bit line BL or the respective word line WL.

The present embodiment is characterized in that in the test operation in FIG. 5D, use is made of the set bit-line voltage VS1, and the time length t3 for the read operation among the characteristic voltages and time lengths, used in the reset operation, set operation, and read operation, respectively. At this point in time, it is important that the set bit-line voltage VS1 is higher than the read bit-line voltage VY1 normally corresponding to the time length t3 for the read operation. Because of this, in a testing state, the time length is t3, the same as the time length in the read operation, however, the voltage as applied is VS1 higher than VY1, so that it is possible to give more stress than that in the read operation to the memory cell, that is, the phase change element.

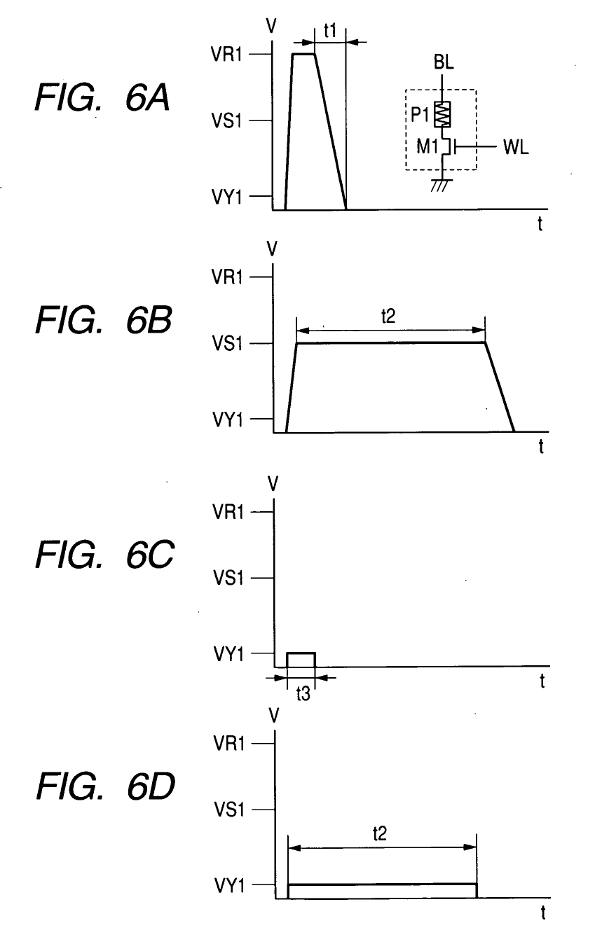

FIG. 6 is a waveform chart showing an example of the operations corresponding to the table in FIG. 4, in which FIGS. 6A, 6B, 6C, and 6D show the reset operation, set operation, read operation, and test operation, respectively. In FIG. 6 as well as with the case of FIG. 5, the test operation is conducted by taking advantage of portions of respective characteristic voltages and time lengths in the reset operation, set operation, and read operation. Further, as with the case of FIG. 5, t1 designates a time length when a voltage is lowered from VR1 to 0V in the reset operation, t2 a time length when the voltage is held at the given voltage VS1 in the set operation, and t3 a time length when the voltage is held at the read bit-line voltage VY1 in the read operation.

In contrast to the case of FIG. 5, in FIG. 6, use is made of the read bit-line voltage VY1, and the time length t2 for voltage application in the set operation. At this point in time, it is important that the time length t2 for voltage application in the set operation is longer than the time length t3 for voltage application in the read operation, normally corresponding to the read bit-line voltage VY1. Because of this, in a testing state, the application voltage is VY1, the same as that in the read operation, however, the time length is t2, longer than that in the read operation, but the same as that in the set operation, so that it is possible to give more stress than that in the read operation to the memory cell, that is, the phase change element.

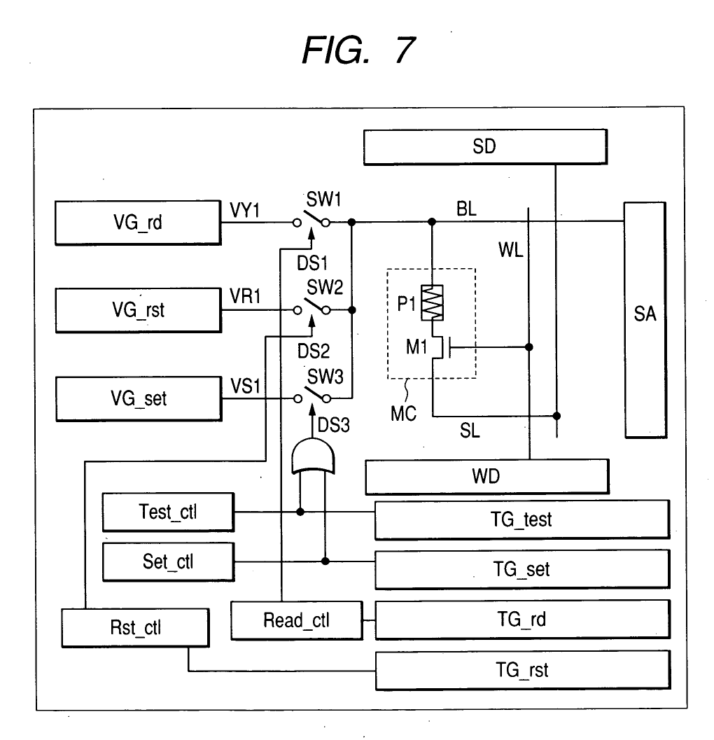

FIG. 7 is a block diagram showing an example of still another configuration of the semiconductor device according to the embodiment, differing from the configuration shown in FIG. 1. The object of the present invention is to check an increase in the number of elements and an increase in chip area as small as possible by utilizing respective portions of the circuits necessary for the reset operation, set operation, and read operation in execution of a test. Accordingly, as shown in FIG. 7, the read/test timing generation circuit TG_rd_test as shown in FIG. 1 and so forth is replaced by a read timing generation circuit TG_rd for use only at the time of read, and a test timing generation circuit TG_test is separately provided. With the use of the test timing generation circuit TG_test, it is possible to check a circuit scale by using the set bit-line voltage power supply VG_set as a power supply circuit while increasing flexibility in time setting at the time of testing.

With the present embodiment, it is possible to select optimum test time so as to match the characteristic of the phase change element, and to execute screening suited for such a purpose. Further, with the present embodiment, it is possible to adopt a configuration wherein selection is made between the case of using the test timing generation circuit TG_test, dedicated for testing, and the case of using other timing generation circuits, for example, one intended for the reading operation, thereby enabling the configuration to match the characteristic of the phase change element in a wider scope.

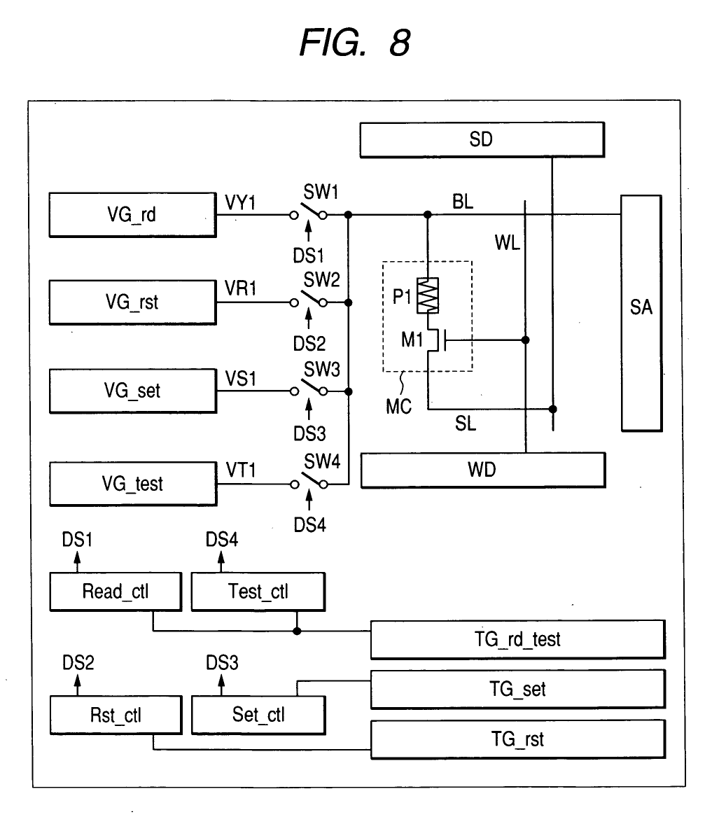

FIG. 8 is a block diagram showing an example of a further configuration of the semiconductor device according to the embodiment, differing from the configuration shown in FIG. 1. With this example, for the timing at the time of testing, use is made of a circuit doubling as the read timing generation circuit, and the test timing generation circuit, however, a test bit-line voltage power supply VG_test (generated voltage: VT1) dedicated for testing is prepared for the voltage at the time of testing, and the generated voltage is applied to a memory array via a switch SW4 controlled by a control terminal DS4.

By so doing, the voltage matching the characteristic of the phase change element can be applied at the time of the test operation, so that higher efficiency of testing can be aimed at. A relationship in magnitude among those generated voltages is generally expressed as follows:
VR1>VS1>VT1>VY1

The test bit-line voltage power supply VG_test can also be implemented simply by providing an external terminal to which the voltage VT1 for testing is applied without use of a power supply circuit such as, for example, a regulator. Further, in such a case, transition from a normal operation to the test operation is possible by detecting supply of the voltage to the external terminal.

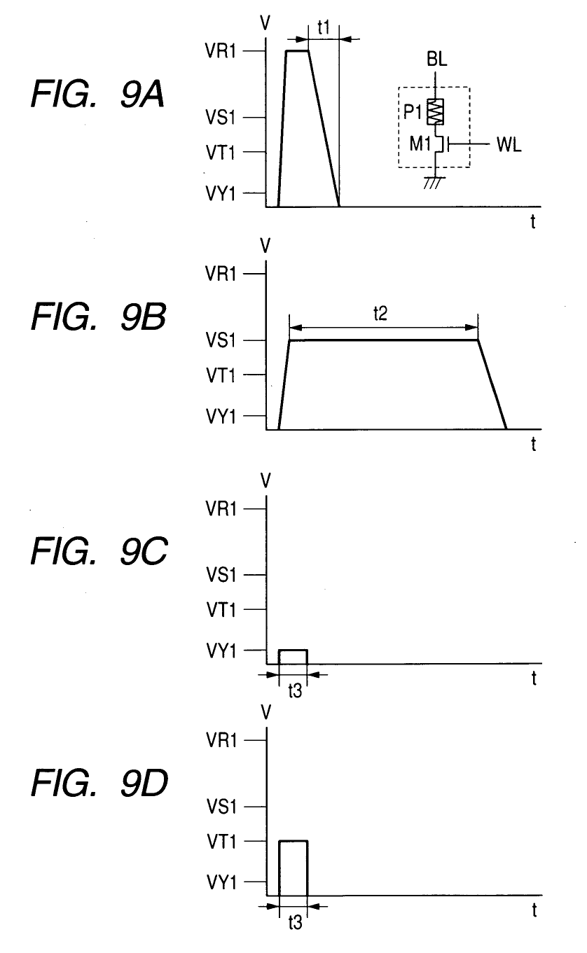

FIG. 9 is a waveform chart showing an example of operations when the configuration in FIG. 8 is adopted, in which FIGS. 9A, 9B, 9C, and 9D show the reset operation, set operation, read operation, and test operation, respectively. In FIG. 9, the horizontal axis is a time axis t, and the vertical axis indicates bit line voltages V applied at respective times along the time axis t. Symbols t1, t2, and t3 indicate characteristic time lengths, respectively, and t1 designates a time length when a voltage is lowered from VR1 to 0V in the reset operation, t2 a time length when the voltage is held at the given voltage VS1 in the set operation, and t3 a time length when the voltage is held at the read bit-line voltage VY1 in the read operation. Those voltages indicate voltages applied to the bit lines BL for the respective memory cells MC selected by the respective bit line BL or the respective word line WL.

With the example shown in FIG. 9, the present embodiment is characterized in that in the test operation, use is made of the voltage VT1 for testing, and the time length t3 for the read operation among the characteristic voltages and time lengths, used in the reset operation, set operation, and read operation, respectively. It is important that the voltage VT1 is lower than the set bit-line voltage VS1, but higher than the read bit-line voltage VY1 normally corresponding to the time length t3 for the read operation. Because of this, in a testing state, a voltage application time length is t3, the same as the time length for voltage application in the read operation, however, the voltage as applied is VT1 higher than VY1, so that it is possible to give more stress than that in the read operation to the phase change element. In addition, VT1 can be set so as to match the characteristic of the phase change element.

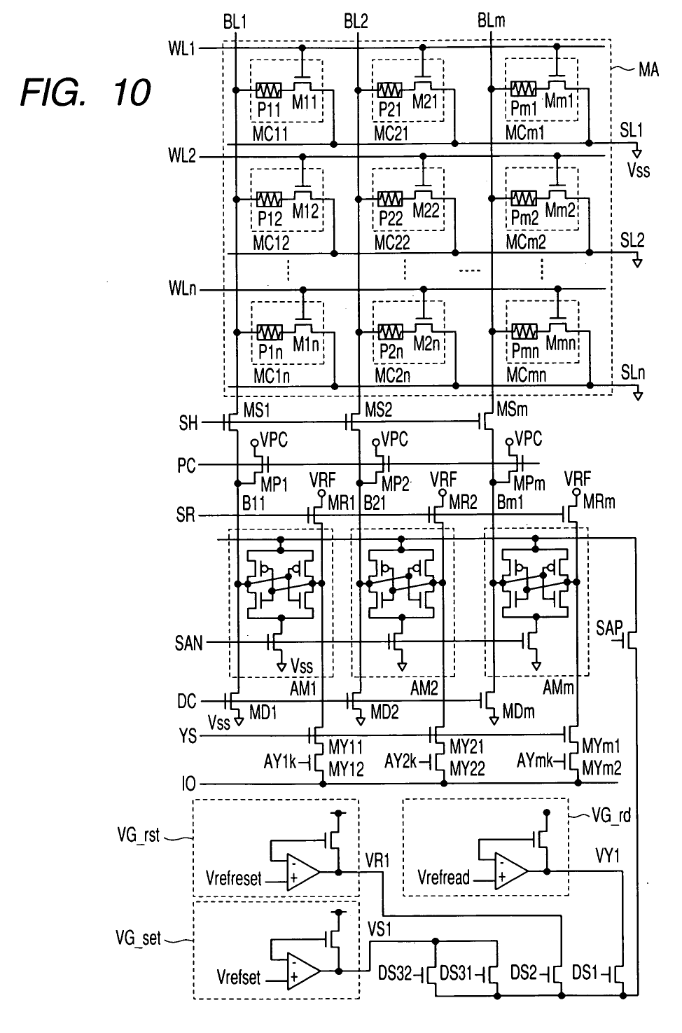

FIG. 10 is a circuit diagram of the semiconductor device according to the embodiment of the invention, showing an example of a detailed configuration thereof, including a memory array configuration. In FIG. 10, MC11 to Mcmn are respective memory cells, and are two-dimensionally arranged to make up the memory array MA. The respective memory cells MC11 to Mcmn comprise respective phase change elements P11 to Pmn, and respective MOS transistors M11 to Mmn, and are configured such that any of the memory cells MC11 to Mcmn can be selected by each of word lines WL1 to WLn, each of bit lines BL1 to Blm, and each of source lines SL1 to Sln.

AM1 to AMm are the so-called cross-coupling amplifiers, respectively, for amplifying respective signals of the bit lines BL1 to Blm, corresponding to the sense amplifier SA shown in FIG. 1, and so forth. SAN, SAP are sense-amplifier startup signals, respectively. Further, MP1 to Mpm are MOS transistors to be controlled by a precharge signal PC, respectively, for precharging the respective bit lines BL1 to Blm to a precharge voltage PVC, MS1 to Msm are MOS transistors to be controlled by a shared signal SH, respectively, for interconnecting the respective bit lines BL1 to Blm, and the respective amplifiers AM1 to AMm, and MR1 to Mrm are MOS transistors to be controlled by a sense-amplifier reference signal SR, respectively, for giving a reference voltage VRF to the respective amplifiers AM1 to AMm.

B11 to Bm1 are respective bit lines on respective sides of the MOS transistors MS1 to Msm, adjacent to the respective amplifiers, and corresponding to the respective bit lines BL1 to Blm, spaced therefrom by the respective MOS transistors MS1 to Msm. Further, MD1 to MDm are MOS transistors to be controlled by a discharge signal DC, respectively, for discharging terminals in the respective amplifiers AM1 to AMm, on respective sides thereof, opposite from the respective references thereof (that is, the respective bit lines B11 to Bm1 on the respective sides of the MOS transistors MS1 to Msm, adjacent to the respective amplifiers) to a ground voltage Vss. Further, terminals in the respective amplifiers AM1 to AMm, on respective sides thereof, in connection with the respective references, are connected to an IO line IO via respective MOS transistors MY11 to Mym1 to be controlled by a Y select signal YS, respectively, and respective MOS transistors MY12 to Mym2, with respective Y address signals AY1k to AYmk inputted thereto, connected in series to the respective MOS transistors MY11 to Mym1.

Further, as an example of a configuration representing the feature of the invention, there are provided the power supplies VG_rst for generating the reset voltage VR1, VG_rd for generating the read voltage VY1, and VG_set for generating the set voltage VS1, respectively, and respective power supply circuits comprise respective reference power supplies Vrefreset for VR1, Vrefread for VY1, and Vrefset for VS1, corresponding to respective voltages as required, respective amplifiers, and respective output transistors.

Those voltages VR1, VY1, and VS1 can be selectively applied to the power supplies of the respective amplifiers AM1 to AMm by respective MOS transistors controlled by the agency of respective switch signals DS1, DS2, DS31, and DS32. In this case, the switch signal DS2 is caused to correspond to the voltage VR1, the switch signal DS1 is caused to correspond to the voltage VY1, and DS31 or DS32 is caused to correspond to the voltage VS1. With the adoption of such a configuration as described, it becomes possible to apply a desired power supply voltage to the respective bit lines BL1 to Blm, and the respective bit lines B11 to Bm1 via the respective amplifiers AM1 to AMm, thereby enabling functions described in the foregoing to be implemented.

FIG. 11 is a waveform chart showing an example of an operation in the case of adopting the configuration shown in FIG. 10. In FIG. 11, there are shown the read operation READ, the reset operation RESET, the set operation SET, and the test operation TEST. First, in the read operation READ, the switch signal DS1 is changed over to thereby select the voltage VY1. At this point in time, the shared signal SH and the discharge signal DC are turned from the high level to the low level, thereby causing the respective bit lines BL1 to Blm, and the respective bit lines B11 to Bm1 to be discharged to Vss so as to be in the floating state.

In this state, the shared signal SH is changed over again, and the precharge signal PC as well as the sense-amplifier reference signal SR is changed over, whereupon the respective bit lines BL1 to Blm, and the respective bit lines B11 to Bm1 are precharged to a voltage VPC, and the voltage VPC becomes an input on one side of each of the amplifiers AM1 to AMm, and an input on the other side thereof is precharged to the reference voltage VRF. Thereafter, the word line WL1 as selected is changed over, and a signal emerges in the respective bit lines BL1 to Blm. That is, as the phase change element can have both a high resistance state and a low resistance state, the signal corresponding to either of the states is read, and the signal is amplified as a result of the respective amplifiers AM1 to AMm being activated following changeover of the respective sense-amplifier startup signals SAN, SAP. In order to fetch the signal as amplified, the Y select signal YS, and the Y. address signal AY1k as selected are changed over. As a result, the signal as read by the IO line IO is outputted.

In the reset operation RESET, the switch signal DS2 is changed over this time to thereby select the voltage VR1. After the initial discharge is released, the shared signal SH, and the respective sense-amplifier startup signals SAN, SAP are changed over, and the voltage VR1 is applied to one of the bit lines (for example, the bit line BL1) . At this point in time, the word line WL1 is changed over, and the transistor of the memory cell is turned ON to thereby apply heat to the phase change element. As a result, one of the phase change elements (for example, P11) is in the melted state.

Thereafter, the word line WL1 is changed over on the falling edge of the time length t1. Accordingly, heat is no longer given to the phase change element (for example, P11), which is rapidly cooled to be thereby turned into the amorphous state. The amorphous state is a state where electrical resistance is high, current is hard to flow even if the transistor of the memory cell is turned ON in the read operation READ, and variation in the voltage of the bit line is small.

In the set operation SET, the switch signal DS31 is changed over this time to thereby select the voltage VS1. This voltage is generally lower than VR1, and higher than VY1. Corresponding to such a relationship in magnitude of the voltages, a relationship in magnitude of heat given to the phase change element becomes similar to the relationship in magnitude of the voltages. After the initial discharge is released, the shared signal SH, and the respective sense-amplifier startup signals SAN, SAP are changed over, and the voltage VS1 is applied to one of the bit lines (for example, the bit line BL1).

At this point in time, the word line WL1 is changed over, and the transistor of the memory cell is turned ON to thereby apply heat to one of the phase change elements (for example, P11). This state is held for the time length t3, whereupon the phase change element (for example, P11) undergoes a change into the crystallization state. The crystallization state is a state where electrical resistance is low, current is easy to flow if the transistor of the memory cell is turned ON in the read operation READ, and variation in the voltage of the bit line is large.

In the test operation TEST, the switch signal DS32 is changed over this time to thereby select the voltage VS1 as with the case of the set operation. In the test operation, the timing for the read operation is applied under this voltage. Accordingly, a time length itself for applying the timing to the phase change element becomes the time length t2. The time length t2 is not sufficient to cause occurrence of the crystallization state in the case of a normal phase change element, giving nothing but stress to the memory element. Then, by detecting a change in the state of the phase change element, due to the stress, it is possible to determine whether or not the phase change element is defective. More specifically, detection of the change in the state of the phase change element is carried out by conducting the test operation on the phase change element in the resetting state, and checking an extent to which transition to the set state has occurred through the read operation.

Now, the configuration shown in FIG. 10 can also be assembled on the basis of the configuration shown in FIG. 8. That is, it is sufficient to adopt a configuration wherein the voltage VT1 dedicated for testing and a generation circuit thereof are provided, and selection of the voltage VT1 can be made by DS32 shown in FIG. 10 (corresponding to DS4 in FIG. 8).

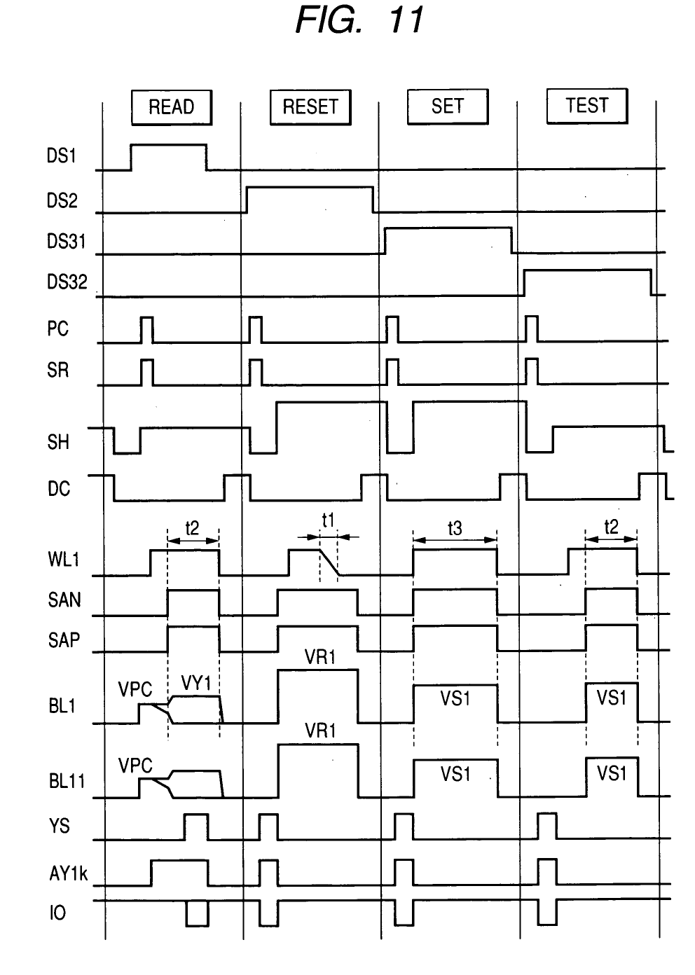

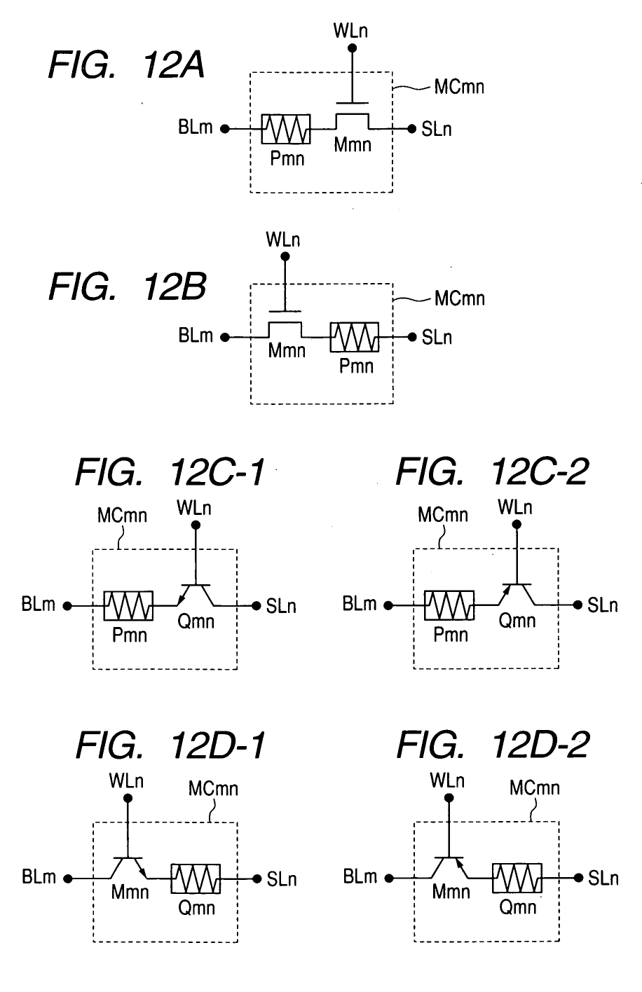

FIG. 12 is a circuit diagram showing examples of the configuration of the memory cells in FIG. 10, and so forth, in which FIGS. 12A, and 12B each are the examples of the memory cell comprising a MOS transistor, and a phase change element, and FIGS. 12(c-1), 12(c-2), 12(d-1), and 12(d-2) each are the examples of the memory cell comprising a bipolar transistor, and a phase change element. In FIGS. 12A, and 12B, a method of driving respective voltages of a bit line Blm and a source line Sln decides on selection of the configuration in either FIG. 12A, or FIG. 12B. In those figures, nMOS transistors are adopted for the MOS transistors, however, there can be the case where easier control is implemented with the adoption of pMOS transistors depending on a method of driving the voltages.

FIGS. 12 (c-1), 12 (c-2), 12 (d-1), and 12 (d-2) each show the cases where the emitter terminal of the bipolar transistor is connected to the phase change element. By so doing, a memory cell area can be rendered smaller. A method of connecting a bit line Blm to a source line Sln decides on selection of the configuration in either of FIGS. 12(c-1), 12(c-2), 12(d-1), and 12 (d-2), depending on the method of driving the respective voltages of the bit line Blm and the source line Sln.

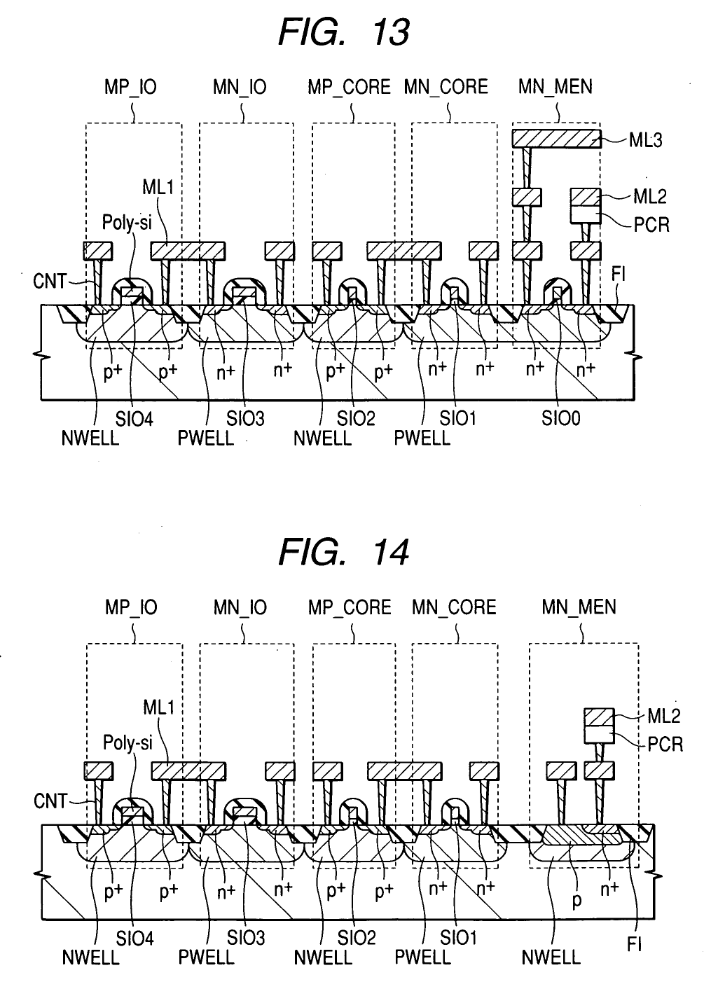

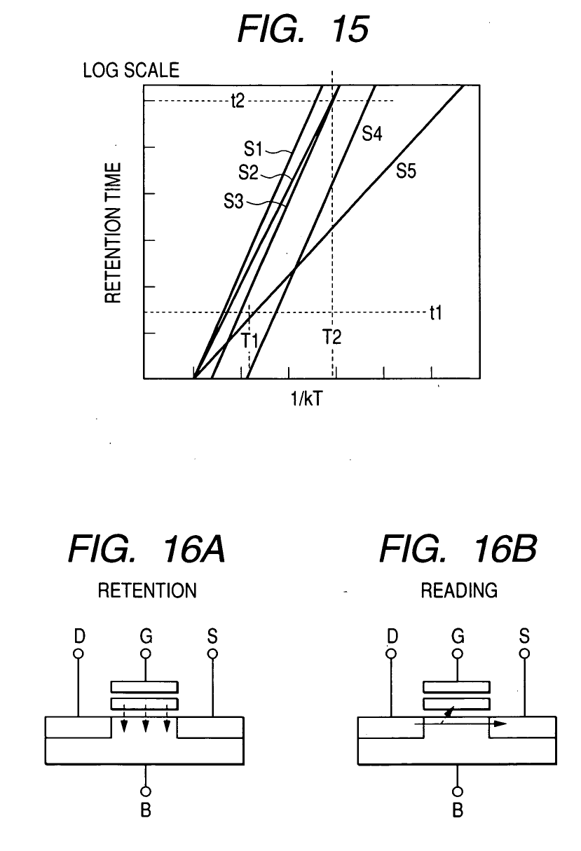

FIG. 13 is a sectional view showing an example of a configuration of the semiconductor device according to the embodiment of invention. With an LSI memory in general, a relatively high voltage is applied from outside to an IO circuit and so forth, and a voltage lower than the former is applied to a decoder circuit, and other logic circuits. Accordingly, with the present embodiment, MOS transistors large in oxidized insulating film thickness are used in parts where the relatively high voltage is applied. Those MOS transistors are MP_IO, and MN_IO, and the insulating film parts thereof are SIO4, and SIO3, respectively.

Further, MOS transistors small in oxidized insulating film thickness are used in parts where the lower voltage is applied. Those MOS transistors are MP_CORE, and MN_CORE, and the insulating film parts thereof are SIO2, and SIO1, respectively. A MOS transistor of a memory cell is MN_MEM, and the insulating film part thereof is SIO0. By rendering SIO0 identical in film thickness to SIO1, it becomes possible to implement a smaller cell area with ease, and by rendering SIO0 identical in film thickness to SIO3, it becomes possible to widen the voltage range that can be handled.

In the figure, a phase change element (PCR) has one face in contact with a contact layer (CNT), a first metal layer (ML1), and another contact layer (CNT), having the other face in contact with a second metal layer (ML2), in one of source/drain regions (n+), to be thereby sandwiched between the two different metal layers. The other of the source/drain regions (n+) is connected up to a third metal layer (ML3) . In the figure, the respective transistors are separated from each other with an isolation insulating film (FI) interposed therebetween, and the respective gates of the transistors are formed of a polysilicon film (Poly-Si) . Further, there is the case of lowering resistance of the source/drain regions, or those of the gate and the source/drain regions by use of silicide or salicide (self-aligned silicide) although not shown in the figure.

FIG. 14 is a sectional view showing an example of another configuration of the semiconductor device according to the embodiment of invention, differing from that shown in FIG. 13. The configuration shown in FIG. 14 differs from that in FIG. 13 in that respective memory cells each comprise a bipolar transistor. The bipolar transistor is an npn bipolar transistor using an emitter layer (n+), a base layer (p), and a collector layer (NWELL), and the emitter layer (n+) is connected to a phase change element (PCR) via a contact layer (CNT), a first metal layer (ML1), and another contact layer (CNT). In the figure, there is shown the case where an electrode is drawn out from the base layer (p) by way of the contact layer (CNT), and the first metal layer (ML1) . A collector region (not shown) is extended in the direction perpendicular to the plane of the figure from the collector layer (NWELL), and the electrode is drawn out through the intermediary of the collector layer. There can be the case where a plurality of the memory cells share the collector layer.

Having specifically described the invention developed by the inventors based on the embodiments of the invention as described above, it is obvious that the invention is not limited thereto, and various changes and modifications may be made in the invention without departing from the spirit and scope thereof.

It is believed that the semiconductor device according to the invention represents a technology useful for application to a semiconductor device using a phase change material, in particular, having, for example, a highly integrated memory circuit, a LOGIC in memory with memory circuits and logic circuits, provided on one and the same semiconductor substrate, and analogue circuits.

What is claimed is:

1. A semiconductor device comprising a plurality of memory cells, the memory cells each comprising a memory element for storing data by taking advantage of a difference in resistance value between a crystallization state and an amorphous state,
wherein at the time of a test operation of the semiconductor device, a first voltage identical to a voltage applied to the memory element when creating the crystallization state is applied to the memory element for only a first time length shorter than a time length for applying the voltage to the memory element when creating the crystallization state.

2. A semiconductor device according to claim 1, wherein the first voltage is generated by sharing a voltage generation circuit for use when turning the memory element into the crystallization state.

3. A semiconductor device according to claim 2, wherein the first time length is identical to a time length for applying a voltage to the memory element when executing a read operation, and is generated by sharing a timing generation circuit for use when executing the read operation to the memory element.

4. A semiconductor device comprising a plurality of memory cells, the memory cells each comprising a memory element for storing data by taking advantage of a difference in resistance value between a crystallization state and an amorphous state,
wherein at the time of a test operation of the semiconductor device, a second voltage higher than a voltage applied to the memory element when executing a read operation to the memory element, but lower than a voltage applied to the memory element when creating the crystallization state is applied to the memory element for only a second time length identical to a time length for applying the voltage to the memory element when executing the read operation.

5. A semiconductor device according to claim 4, wherein the second time length is generated by shared use of a timing generation circuit for use when executing the read operation to the memory element.

6. A semiconductor device according to claim 4, wherein the second voltage is inputted from an external terminal.

7. A semiconductor device comprising a plurality of memory cells, the memory cells each comprising a memory element for storing data by taking advantage of a difference in resistance value between a crystallization state and an amorphous state,
wherein at the time of a test operation of the semiconductor device, a third voltage identical to a voltage applied to the memory element when executing a read operation to the memory element is applied to the memory element for only a third time length identical to a time length for applying the voltage to the memory element when creating the crystallization state.

8. A semiconductor device according to claim 7, wherein the third voltage is generated by sharing a voltage generation circuit for use when executing the read operation to the memory element, and the third time length is generated by sharing a timing generation circuit for use when turning the memory element into the crystallization state.

9. A semiconductor device according to claim 1, wherein the memory element is composed of a chalcogenide material.

10. A semiconductor device according to claim 4, wherein the memory element is composed of a chalcogenide material.

11. A semiconductor device according to claim 7, wherein the memory element is composed of a chalcogenide material.
